(19) United States
(12) Patent Application Publication
(10) Pub. No.: US 2025/0308549 A1
(43) Pub. Date: Oct. 2, 2025

(54) Spintronic Reader Utilizing The Inverse Spin Hall Effect

(71) Applicant: Headway Technologies, Inc., Milpitas, CA (US)

(72) Inventors: Bernard Dieny, Lans en Vercors (FR); Moris Musa Dovek, San Jose, CA (US)

(21) Appl. No.: 18/623,991

(22) Filed: Apr. 1, 2024

(51) Int. Cl. G11B 5/37; G11B 5/39; H10N 50/01; H10N 50/10; H10N 50/20; H10N 50/85; H10N 52/01; H10N 52/80

(52) U.S. Cl. CPC G11B 5/374; G11B 5/3912; H10N 50/01; H10N 50/10; H10N 50/20; H10N 50/85; H10N 52/01; H10N 52/80

(57) ABSTRACT

The present embodiments relate to reader designs that incorporate Inverse Spin Hall Effect (ISHE). ISHE can convert part of a longitudinal spin-current into a transversal charge current where a spin-current can be created by flowing a charge current in the perpendicular to plane direction (CPP current) through a sense magnetic layer adjacent to the material with spin orbit interactions. The spintronic reader can include a stack of layers that includes a sense layer with a magnetization configured to be biased primarily in a cross-track direction relative to an air-bearing surface (ABS), a spin-orbit layer characterized by a spin hall angle, and an electrical contact layer disposed adjacent to the spin-orbit layer to enable a current to flow throughout the sense layer and spin orbit layer.

### TECHNICAL FIELD

Embodiments of the invention relate to the field of electro-mechanical data storage devices. More particularly, embodiments of the invention relate to a stack of layers for a spintronic reader that incorporates an Inverse Spin Hall Effect.

### BACKGROUND

A magnetic recording medium (e.g., a magnetic disk) can store magnetic bits representing digital data. A magneto-resistive writer can be part of a hard disk drive (HDD) to write digital data to the magnetic recording medium.

As an overall amount of digital data being stored on HDD devices increases, there is an increasing demand for increased data capacity of HDD devices. One technique to increase data capacity for an HDD can include heat-assisted magnetic recording (HAMR) or microwave-assisted magnetic recording (MAMR). HAMR and MAMR techniques increase the density of HDDs by manipulating a portion of the magnetic recording medium, which can enhance write performance of the write head to the magnetic recording medium.

Further, spintronic readers can be used in hard disk drives to readout the state of the magnetic bits written in the media. Spintronic readers are generally based on a tunnel magnetoresistance (TMR) of magnetic tunnel junctions (MTJ). MTJs can include a sense layer with a magnetization that rotates under the influence of the field coming from the media, and a reference layer of fixed magnetization. These magnetic layers can be separated by a tunnel barrier, which can be made of a material such as magnesium oxide (MgO). The change in the relative orientation of the magnetization of the sense and reference layer can produce the TMR signal.

### SUMMARY

The present embodiments relate to reader designs that incorporate Inverse Spin Hall Effect (ISHE). ISHE can convert a longitudinal spin-current into a transversal charge current where a spin-current can be created by flowing a charge current in the perpendicular to plane direction (CPP current) through a sense magnetic layer adjacent to the material with spin orbit interactions. The spintronic reader can include a stack of layers that includes a sense layer with a magnetization configured to be biased primarily in a cross-track direction relative to an air-bearing surface (ABS), a spin-orbit layer characterized by a spin hall angle, and an electrical contact layer disposed adjacent to the spin-orbit layer.

In a first example embodiment, a spintronic reader for a hard disk drive is provided. The reader can include a stack of layers providing an inverse spin hall effect (ISHE). The stack can include a sense layer with a magnetization configured to be biased primarily in a cross-track direction relative to an air-bearing surface (ABS), the sense layer comprising a first length at the ABS in the cross-track direction. The stack can also include a spin-orbit layer, wherein the spin-orbit layer comprises a second length of a first side that is greater than the first length of the sense layer at the ABS in the cross-track direction, and wherein the spin-orbit layer is characterized by a spin hall angle. The stack can also include an electrical contact layer disposed adjacent to the spin-orbit layer to enable a sense current to flow throughout the sense layer and spin orbit layer.

In some instances, the spin-orbit layer is configured to enable electrical contacts to be disposed over a first area of the spin-orbit layer that extends beyond a second area covered by the sense layer.

In some instances, the spin hall angle is larger than 8 degrees or larger than 30 degrees in absolute values.

In some instances, the reader also includes an electrical component configured to flow a spin-polarized current in a direction perpendicular to a plane direction throughout the sense layer and the spin-orbit layer.

In some instances, the reader also includes an output amplifier device comprising a pre-amplifier.

In some instances, a first conductor is configured to electrically connect an area of the spin-orbit layer not covered by the sense layer to a first input of the output amplifier device, wherein a second input of the output amplifier device is connected to any of bottom or a top layer of the stack.

In some instances, the sense layer comprises any of a first set of materials comprising Iron (Fe), Cobalt (Co), Nickel (Ni), or any of the first set of materials with an addition of any of Boron (B), Niobium (Nb), Zirconium (Zr), or Hafnium (Hr).

In some instances, the spin orbit layer is made of a material with a large spin-orbit interaction including any of Tantalum (Ta), Platinum (Pt), Tungsten (W), Bismuth (Bi), Gold (Au), a CuBi alloy, a AuW alloy.

In some instances, the reader also includes a first tunnel barrier disposed between the sense layer and the spin-orbit layer, wherein the first tunnel has a resistance area product below 5 ohms per squared micrometer (Ω·μm²).

In some instances, the reader also includes a second tunnel barrier disposed between spin-orbit layer and the electrical contact layer, wherein any of the first tunnel barrier and second tunnel barrier comprise any of Aluminum oxide (AlOx), Titanium Oxide (TiOx), Hafnium Oxide (HfOx), Tantalum Oxide (TaOx), Magnesium Oxide (MgO).

In some instances, each of the first tunnel barrier and the second tunnel barrier comprise layers each with current confined paths, wherein the current confined paths are formed by mixing a metallic non-magnetic material with an oxide material.

In some instances, the spin-orbit layer comprises a length of a second side of the spin-orbit layer that is greater than the first length of the sense layer such that the spin-orbit layer extends past each opposing side of the sense layer at the ABS surface in the cross-track direction.

In another example embodiment, a reader stack is provided. The reader stack can include a sense layer with a magnetization configured to be biased primarily in a cross-track direction relative to an air-bearing surface (ABS). The reader stack can also include a spin-orbit layer, and wherein the spin-orbit layer is characterized by a spin hall angle. The reader stack can also include an electrical contact layer disposed adjacent to the spin-orbit layer.

In some instances, the sense layer comprises a first length at the ABS in the cross-track direction, and wherein the spin-orbit layer comprises a second length of a first side that is greater than the first length of the sense layer at the ABS in the cross-track direction.

In some instances, the reader stack can also include a first magnetic shield disposed at a first end of the reader stack and a second magnetic shield disposed at a second end of the reader stack.

In some instances, the reader stack can also include a first tunnel barrier disposed between the sense layer and the spin-orbit layer, wherein the first tunnel barrier has a resistance area product below 5 ohms per squared micrometer (Ω·μm²), and a second tunnel barrier disposed between spin-orbit layer and the electrical contact layer, wherein any of the first tunnel barrier and second tunnel barrier comprise any of Aluminum oxide (AlOx), Titanium Oxide (TiOx), Hafnium Oxide (HfOx), Tantalum Oxide (TaOx), Magnesium Oxide (MgO).

In some instances, each of the first tunnel barrier and the second tunnel barrier comprise layers each with current confined paths, wherein the current confined paths are formed by mixing a metallic non-magnetic material with an oxide material.

In another example embodiment, a method is provided. the method can include forming a stack of layers providing an inverse spin hall effect (ISHE) for a spintronic reader of a hard disk drive by providing a sense layer with a magnetization configured to be biased primarily in a cross-track direction relative to an air-bearing surface (ABS), the sense layer comprising a first length at the ABS in the cross-track direction. Forming the stack can also include disposing a spin-orbit layer adjacent to the sense layer, wherein the spin-orbit layer comprises a second length of a first side that is greater than the first length of the sense layer at the ABS in the cross-track direction, and wherein the spin-orbit layer is characterized by a spin hall angle. Forming the stack can also include disposing an electrical contact layer adjacent to the spin-orbit layer to enable a current to flow throughout the sense layer and spin-orbit layer. Forming the stack can also include disposing a first magnetic shield at a first end of the stack and a second magnetic shield disposed at a second end of the stack.

In some instances, the method also includes providing a current by an electrical component to flow a spin-polarized current in a direction perpendicular to a plane direction throughout the sense layer and the spin-orbit layer.

In some instances, the method also includes forming a first tunnel barrier disposed between the sense layer and the spin-orbit layer, wherein the first tunnel has a resistance area product below 5 ohms per squared micrometer (Ω·μm²), and forming a second tunnel barrier disposed between spin-orbit layer and the electrical contact layer, wherein any of the first tunnel barrier and second tunnel barrier comprise any of Aluminum oxide (AlOx), Titanium Oxide (TiOx), Hafnium Oxide (HfOx), Tantalum Oxide (TaOx), Magnesium Oxide (MgO).

Other features and advantages of embodiments of the present invention will be apparent from the accompanying drawings and from the detailed description that follows.

### BRIEF DESCRIPTION OF THE DRAWINGS

Embodiments of the present invention are illustrated by way of example and not limitation in the figures of the accompanying drawings, in which like references indicate similar elements and in which:

FIG. 1 illustrates an example cross-sectional view of a conventional TMR write head.

FIGS. 2A-2C illustrate example spintronic effects resulting from spin orbit interaction in a spin orbit material according to an embodiment.

FIG. 3 is an example illustration of an operation of a ISHE reader according to an embodiment.

FIG. 4A is an example illustration of the phenomenon of current back-flow appearing in the ISHE structure if no tunnel barrier or layer with current confined path is introduced between the SO layer and the SL as well as between the SO and the nonmagnetic metallic underlayer according to an embodiment.

FIG. 4B illustrates an example of reduction of the back-flow currents in the SL and nonmagnetic underlayer by introducing tunnel barriers or layers with current confined paths at the interfaces between the SO layer and SL and non-magnetic underlayer according to an embodiment.

FIG. 5 illustrates a ISHE head embodiment in which two tunnel barriers have been inserted between the SO layer and the sense layer as well as between the SO layer and the Bottom electrical contact to avoid current back flow in these layers according to an embodiment.

FIG. 6 is an example ABS view of the ISHE reader in which the two connections to the ISHE device are made for the first one on the widen part of the SO layer and for the second one on one of the two shields according to an embodiment.

FIG. 7 is an example ABS view of the ISHE reader in which the bottom conducting layer has been removed so that the sense current tunnel directly from the SO layer to shield 1 according to an embodiment.

FIG. 8 is an example illustration of an ABS view of the ISHE reader in which the two connections to the ISHE device are made on the two widen parts of the SO layer patterned on both sides of the ISHE device according to an embodiment.

FIG. 9 is an example ABS view of the ISHE reader in which the bottom conducting layer has been removed so that the sense current tunnel directly from the SO layer to shield 1 according to an embodiment.

### DETAILED DESCRIPTION

A disk drive can include a write head to interact with a magnetic recording medium to read and write digital data to the magnetic recording medium. As the amount of digital data is required to be stored increases and with an increase in data aerial density of hard disk drive (HDD) writing, both the write head and digital data written to the magnetic recording medium can generally be made smaller.

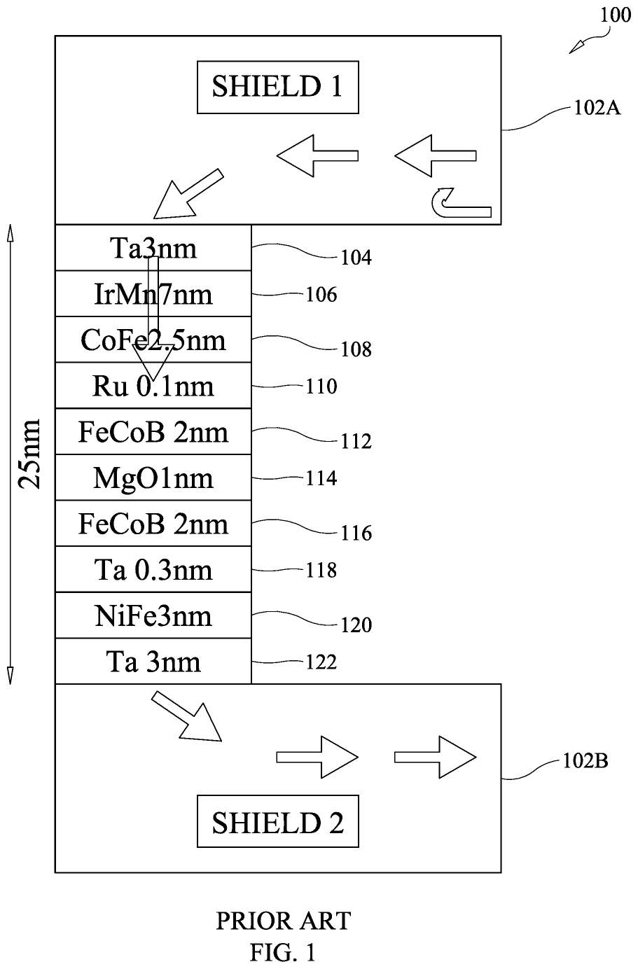

Further, spintronic readers can be used in hard disk drives to readout the state of the magnetic bits written in the media. Spintronic readers are generally based on a tunnel magnetoresistance (TMR) of magnetic tunnel junctions (MTJ). MTJs can include a sense layer with a magnetization that rotates under the influence of the field coming from the media, and a reference layer of fixed magnetization. These magnetic layers can be separated by a tunnel barrier, which can be made of a material such as magnesium oxide (MgO). The change in the relative orientation of the magnetization of the sense and reference layer can produce the TMR signal. The reference layer can be pinned in the direction roughly parallel to the field to be measured (out-of-the-plane of the media) when using perpendicular media. This pinning can be achieved by coupling the reference layer to a synthetic antiferromagnetic layer itself pinned by an antiferromagnetic (e.g., Iridium (Ir) and Manganese (Mn) (Ir20Mn80)) pinning layer. An example composition of such magnetic tunnel junction can include IrMn 6 nm/CoFe 2.5 nm/Ruthenium (Ru) 0.8 nm/CoFe 2 nm/Tantalum (Ta) 0.3 nm/FeCoB 3 nm/MgO 1 nm/FeCoB 5 nm/Ta 2 nm which can represent a total thickness of at least 22 nm or 25 nm. An example of this junction can be shown in FIG. 1.

FIG. 1 illustrates an example cross-sectional view of a TMR write head 100. For example, in FIG. 1, a head 100 can include shields 102A-B and a stack disposed between shields 102A-B. The stack can include Ta 0.3 nm (104), IrMn7 nm (106), CoFe2.5 nm (108), Ru0.8 nm (110), FeCoB 2 nm (112), MgO 1 nm (114), FeCoB 2 nm (116), Ta 0.3 nm (118), NiFe 3 nm (120), and Ta 3 nm (122).

Further, a magneto-resistive device can be inserted between two shields made of soft magnetic material which can absorb the flux from further bits along the track so that the magneto-resistive sensor mostly detects the magnetic flux from the bit located right under the sensor at the air bearing surface (ABS). The shield to shield spacing can influence the head performance since it can determine the down-track resolution and therefore the maximum kilo flux change per inch (KFCI) that the head can read. The shorter the gap length in the down-track direction, the larger the maximum KFCI the reader can read.

Efforts have been put into trying to reduce the gap length without excessively compromising on the amplitude and noise of the readout signal. The thickness of each layer involved in the stack can be reduced as much as possible and a scheme of recessed pinning layer can be used consisting in recessing the antiferromagnetic pinning layer away from the ABS to reduce the total thickness of the stack next to the ABS. However, it can be difficult to further reduce the read gap (25 nm) length without a significant change in the read head design.

The present embodiments relate to changing the working principle of the reader by using another spintronic effect called Inverse Spin Hall Effect (ISHE) instead of the tunnel magnetoresistance effect (TMR) used in other magneto-resistive readers. ISHE can be a consequence of the spin-orbit effect which takes place in heavy metal material such as Platinum (Pt), Gold (Au), Tungsten (W), Tantalum (Ta), Bismuth (Bi), or alloys such as Gold-Tungsten (AuW), Copper-Bismuth (CuBi), Copper-Iridium (CuIr), etc., or other materials such as topological insulators.

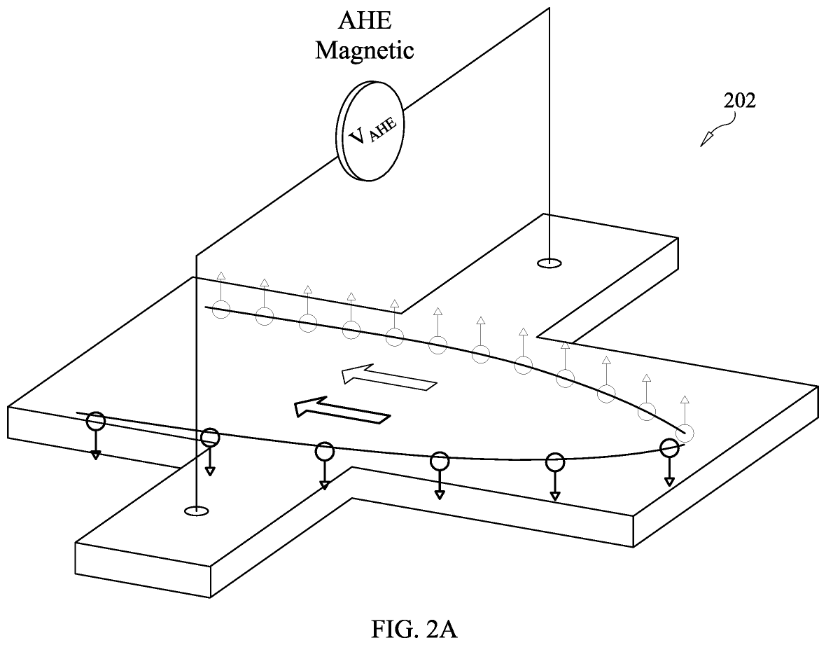

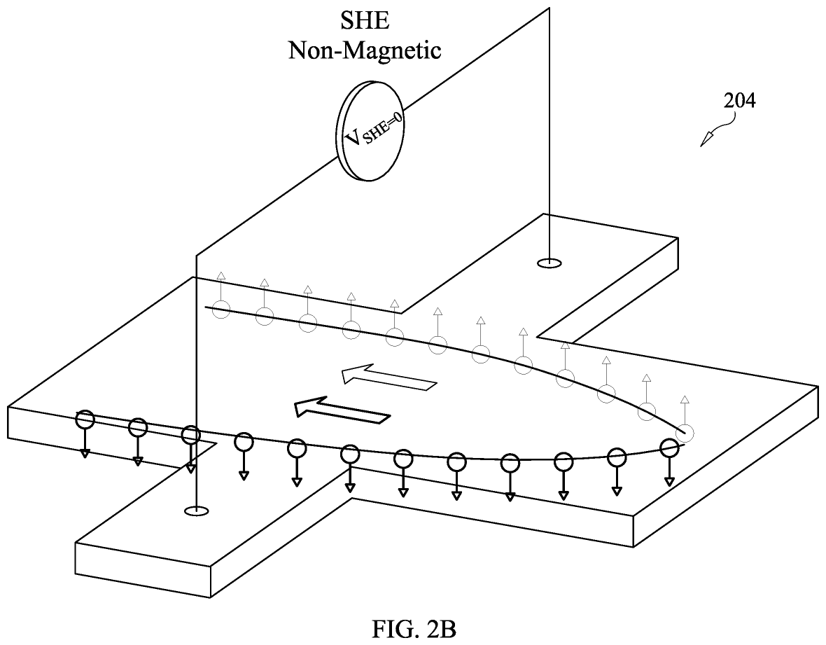

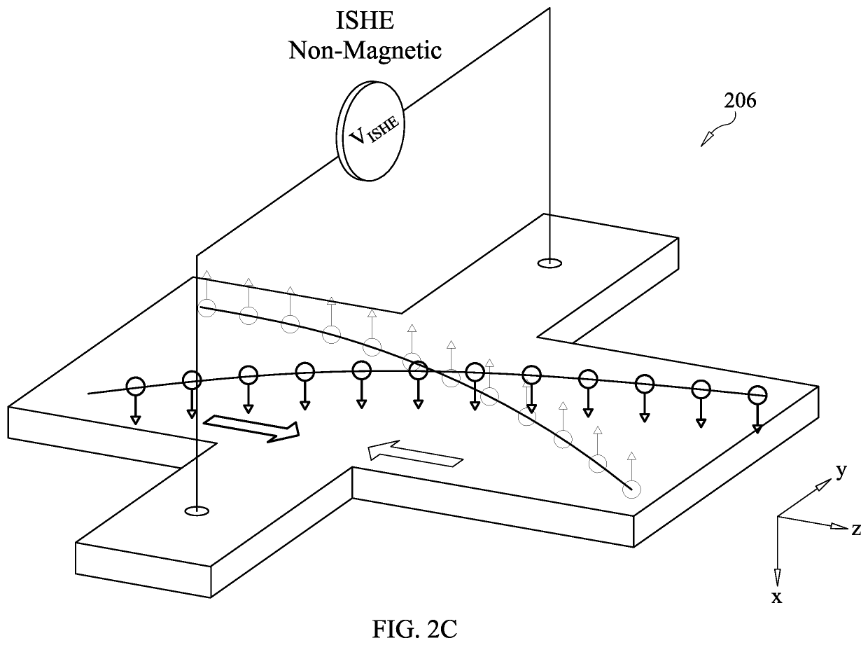

The ISHE principle consists in converting part of a longitudinal spin-current into a transversal charge current, as illustrated in FIG. 2C, for example. In the reader designs as described herein, the spin-current can be created by flowing a charge current in the perpendicular to plane direction (CPP current) through a sense magnetic layer adjacent to the material with spin orbit interactions.

FIG. 2 illustrates example spintronic effects resulting from spin orbit interaction in a spin orbit material. For instance, a first material 202 illustrates an example Anomalous Hall Effect (AHE) in which a spin-polarized current in a magnetic material creates a transverse charge current (yielding a transverse voltage if open circuit) (See FIG. 2A). A second material 204 illustrates an example Spin Hall effect (SHE) in which an unpolarized charge current in a non-magnetic material creates a transverse spin-current (yielding lateral spin accumulation if open circuit) (see FIG. 2B). A third example material 206 illustrates an example Inverse Spin Hall Effect (ISHE) in which a spin-current injected in a non-magnetic material creates a transverse charge current (yielding a transverse voltage in open circuit) (See FIG. 2C). In the third material, the x-axis is along the spin polarization, the z-axis is along the sense-current flow, the y-axis is along the electrical field generated by the ISHE.

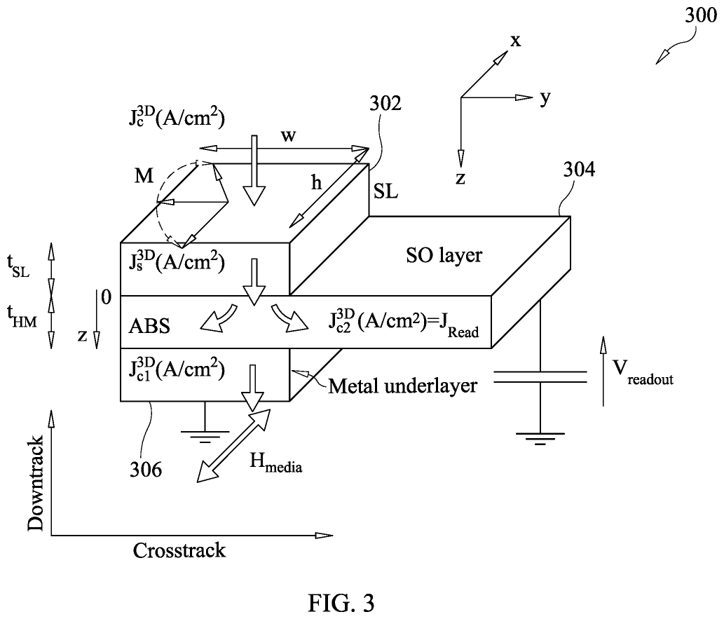

The sense magnetic layer can be made of a soft magnetic material such as permalloy (Ni₈₀Fe₂₀), an Iron-Cobalt-Boron (FeCoB) alloy or a soft multilayer combining a NiFe alloy and FeCo alloy or a soft magnetic multilayer comprising non-magnetic insertion layers such as Cu, the purpose of which being to shorten the spin diffusion length in the sense layer or any combination of these materials. The spin-dependent scattering occurring in the magnetic sense layer can yield a net spin polarization of the current, and therefore a spin-current can be injected in the spin-orbit layer. Since the magnetization of the sense layer varies in orientation in response to the variation of magnetic field from media, variation in Mx can yield variation in the S spin-current (S spin-current can define a current polarized in the x-direction and propagating in the z-direction) and consequently in the transverse charge current generated in the spin-orbit material propagating in the y direction (see FIG. 3). A transverse charge current in the spin-orbit layer can provide the readout current Iread which can be amplified with a pre-amplifier yielding the readout signal (V readout).

The advantage of this approach can be that no reference layer can be required in the reader in contrast to the case of a TMR reader. The reader can include a sense layer (SL) and a spin orbit layer (SO) so that its total thickness is dramatically reduced compared to that of a TMR reader resulting in a much shorter shield to shield spacing. The thickness of the sense layer can be of a few nanometers to maintain a sufficient volume of this layer so as to minimize the thermally induced fluctuations of its magnetization.

FIG. 3 is an example illustration of an operation of a ISHE reader 300. The reader can be shown from the air bearing surface (ABS). As shown in FIG. 3, the reader 300 can include any of a SL layer 302, a SO layer 304, and a metal underlayer 306. A sense current with a current density We can be injected in the reader (top vertical arrow), gets spin-polarized while traversing the sense layer (SL) and the resulting spin-current flowing in the spin orbit layer (SO) is partly deviated in the transversal direction generating a transverse readout charge current density Ja. This readout current density can be modulated by the rotation of the sense layer magnetization under the variation of the magnetic field from media H_{media}. This current density integrated on the cross section of the SO layer can constitute the readout current which can be measured to determine the magnetic field from the media. The x-axis can be along the spin polarization direction which is here defined by the magnetization of the sense layer along the in-out of ABS direction, the z-axis is along the sense-current flow (down-track direction), the y-axis is along the electrical field generated by the ISHE (cross-track direction).

For instance, in the case of a sense layer made of a permalloy, the thickness of the layer can be of the order of 4 to 8 nm. Similarly, the thickness of the spin-orbit layer can be of the order of 2 to 4 nm, with the spin-orbit layer being made of a material with large spin Hall angle, large electrical resistivity, and long spin-diffusion length. As a result, the total thickness of the SL/SO bilayer can be of the order of 6 nm to 12 nm, much below the 25 nm of conventional TMR stacks. Nevertheless, additional functional layers can be used which add some extra thickness to the ISHE stack but still reduce the total thickness by a factor 2 by using a ISHE reader rather than a TMR reader. This can translate into an increase by about a factor of 2 in the KFCI capability of the reader compared to conventional TMR readers.

In some instances, the present embodiments relate to a spintronic reader for hard disk drives based on Inverse Spin Hall Effect. A spintronic reader can include an ISHE reader stack which includes a sense layer presenting a first dimension at the air bearing surface in the cross-track direction. The magnetization of the sense layer can be biased approximately in the cross-track direction. The stack can also include a layer made of a material with spin-orbit interactions presenting a second dimension at the air bearing surface in the cross-track direction. The second dimension can be larger than the first dimension enabling electrical contacts to be taken over the area extending in the material with spin-orbit beyond the area covered by the sense layer. The spin orbit layer can have a Spin Hall Angle being larger than 8° and larger than 30° in absolute values. The sense layer and spin orbit layer can be stacked so that a spin-polarized current can be transmitted from the sense layer to the spin-orbit layer. The stack can also include an electrical bottom contact layer located on the face of the layer with spin-orbit opposite to that facing the sense layer.

The reader can allow for a flow of a current in the perpendicular to plane direction between the sense layer and the electrical bottom contact layer. The reader can also include an output amplifier device such as a pre-amplifier.

In some instances, the spintronic reader can include a low resistance conductor that connects the area of the spin orbit layer uncovered by the sense layer to one input of the amplifier device. The second input can be connected to the bottom or top layer of the ISHE reader stack.

In some instances, the sense layer comprises a layer of magnetically soft alloy made of Fe, Co, Ni with possible addition of amorphising element such as Boron (B), Niobium (Nb), Zirconium (Zr), Hafnium (Hf), or a combination of these alloys.

In some instances, the spin orbit layer is made of a material with large spin orbit interaction such as Ta, Pt, β-W, Bi, Au, CuBi alloy, AuW alloy or a topological insulator.

In some instances, the spin-orbit layer is made of a material in which the product Θ_{SHE}ρ_{SO}l_{SF}^{SO} is at least of 50 and preferably at least 100 and at least 150, where Θ_{SHE} is the spin Hall angle of the spin-orbit material (no unit), ρ_{SO} is the resistivity of this material expressed in μΩ·cm, and l_{SF}^{SO} is the spin-diffusion length in this material expressed in nm.

In some instances, the sense layer and the spin-orbit layer are separated by a first tunnel barrier of low-resistance area product below 5 Ω·μm² and preferably below 1 Ω·μm² and preferably below 0.3 Ω·μm².

In some instances, the first tunnel barrier is made of an insulating oxide or nitride such as Aluminum Oxide (AlOx), Titanium Oxide (TiOx), Hafnium Oxide (HfOx), Tantalum Oxide (TaOx), Magnesium Oxide (MgO).

In some instances, a second tunnel barrier is inserted at the interface of the spin orbit layer opposite to the interface with the first tunnel barrier.

In some instances, the second tunnel barrier is made of an insulating oxide or nitride such as AlOx, AlNx, TiOx, HfOx, TaOx and preferably of MgO.

In some instances, the tunnel barriers are replaced by layers with current confined paths.

In some instances, the current confined paths layers are formed by mixing a metallic nonmagnetic species as for instance Cu, Ag, Au with an oxide material such as AlOx, MgO, TaOx, HfOx.

In some instances, the spin-orbit layer can present a third dimension larger than the first dimension such that the spin-orbit layer extends on both side of the sense layer at the air bearing surface in the cross-track direction.

In some instances, low resistance electrical leads connect the two areas extending in the spin-orbit layer beyond the area covered by the sense layer to the two inputs of the amplifier device.

In some instances, the spintronic ISHE reader stack is sandwiched between two magnetic shields.

In some instances, the electrical bottom contact layer of the ISHE stack located on the face of the layer with spin-orbit opposite to that facing the sense layer is one of the shield sandwiching the ISHE reader stack.

The stacks as described herein can differ from those used in TMR heads and additional electrical contacts can be used so that this head is a 3 or 4-terminal device whereas other TMR heads can only have two contacts, one at the bottom of the magnetic tunnel junction (MTJ), the other at the top of the MTJ.

The present reader designs can use a different physical principle compared to other magneto-resistive heads which were based on the anisotropic magnetoresistance (AMR), giant magnetoresistance (GMR), or tunnel magnetoresistance. The present reader designs may not rely on these spintronic phenomena but rather on ISHE. The stacks used in the present designs can be different from those used in TMR heads. Such designs may only include a sense layer without a pinned reference layer. Further, the present head designs can use additional electrical contact(s) built in the cross-track direction of the ISHE stack.

The present designs of a spintronic head can rely on the Inverse Spin Hall Effect (ISHE) which can be a consequence of spin orbit interactions present in some materials such as heavy metals or topological insulators. Heavy metals are metals with large atomic number (Z), such as above Z>40. The spin-orbit interaction can grow very rapidly with the atomic number (Z). Simple quantum mechanical models yield a Z⁴ dependence of the spin orbit interaction on the atomic number of the considered metal.

ISHE is one of three spintronic effects resulting from spin orbit interactions in heavy metal materials as illustrated in FIG. 2. A first effect is the anomalous Hall Effect (AHE) which arises when a spin-polarized current flows in a magnetic material with out-of-plane magnetization, creating a transverse charge current (yielding a transverse voltage in open circuit). A second effect is the Spin Hall Effect (SHE) in which an unpolarized charge current flowing in a non-magnetic material where spin-orbit creates a transverse spin-current (yielding lateral spin accumulation in open circuit). The third effect is the Inverse Spin Hall Effect (ISHE) in which a spin-polarized charge current injected in a non-magnetic material with spin-orbit creates a transverse charge current (yielding a transverse voltage in open circuit). Spin-orbit can enable interconversion between spin and charge currents. FIG. 3 illustrates how ISHE can be used to readout the magnetic field from media when the reader flies above a track and is subjected to the variable field H_{media} from the written bits.

FIG. 3 may illustrate the sense layer (SL), the layer with spin-orbit (SO) and a conducting underlayer, where the purpose of which is to be able to flow a current perpendicular to plane in throughout the stack from the sense layer to this conducting underlayer. As represented in FIG. 3, the sense layer can have an area smaller than the SO layer in the cross-track direction so that an electrical contact can be made on the part of the SO layer not covered by the sense layer. The magnetization of the sense layer can be biased in the cross-track direction. Different techniques used in GMR or TMR heads can be used to achieve such bias either by using permanent magnets or side soft magnetic layers exchange coupled to the shields. These same techniques for biasing the sense layer can be used here.

Then, under the influence of the field from the media, the magnetization of the sense layer can rotate upward or downward perpendicularly to the air bearing surface. When a sense current is injected throughout the SL/SO stack with a current density l_{c}^{3D}, this current can get spin-polarized as it traverses the sense layer due to spin-dependent scattering within this layer. As known from Valet and Fert theory of current perpendicular to plane GMR, the spin-polarization can build up on a length scale given by the spin diffusion length in the material constituting the sense layer l_{SF}^{SL}. If the thickness of the sense layer t_{SL} is of the order of l_{SF}^{SL} or larger, then the resulting spin current exiting the sense layer is given by Jₛ^{3D}=β_{J}^{3D} where β is the spin-scattering asymmetry as defined in Valet and Fert theory. In this expression, the bulk spin-dependent scattering may be considered, but it is known that the scattering asymmetry may also have interfacial contribution, especially if the sense layer comprises laminations of additional material such as very thin laminations of Cu which may be used to shorten the spin-diffusion length in the sense layer and to increase the scattering asymmetry and therefore the spin polarization of the current in the sense layer. The interfacial scattering asymmetry is described by the parameter γ in Valet and Fert theory.

In materials such as Permalloy or CoFe alloys or FeCoB alloys, the spin polarization of the current can reach values of the order of 60% to 80% when the thickness of this layer gets of the order of the spin-diffusion length. This spin-polarized current then flows in the spin orbit layer (SO). There, due to spin-orbit interactions, the electrons are partly deflected in the direction given by the cross-product \vec{J_{c}^{3D}}×\vec{M}.

The component of this current in the y-direction results in a transverse charge current density given by

$${J}_{c 2}^{3 D} = {Θ}_{SHE} {J}_{S}^{3 D} exp ( - \frac{z}{{l}_{SF}^{SO}} )$$

where Θ_{SHE} is the so-called Spin Hall angle. Θ_{SHE} characterizes the efficiency of the interconversion between charge and spin current. Here are a few examples: Θ_{SHE}=8.5% in Pt, Θ_{SHE}=7.1% in Ta, Θ_{SHE}=10% in AuW alloy, Θ_{SHE}=33% in βW which is the beta phase of wolfram (Tungsten). As indicated in FIG. 3, the z coordinate is the depth within the SO layer from the interface with the adjacent layer from which the spin polarized current penetrates in the SO layer.

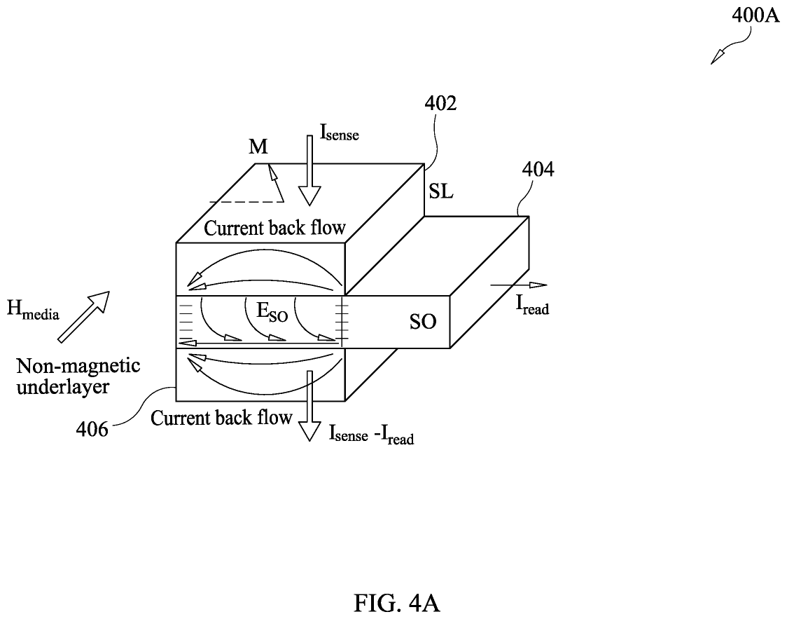

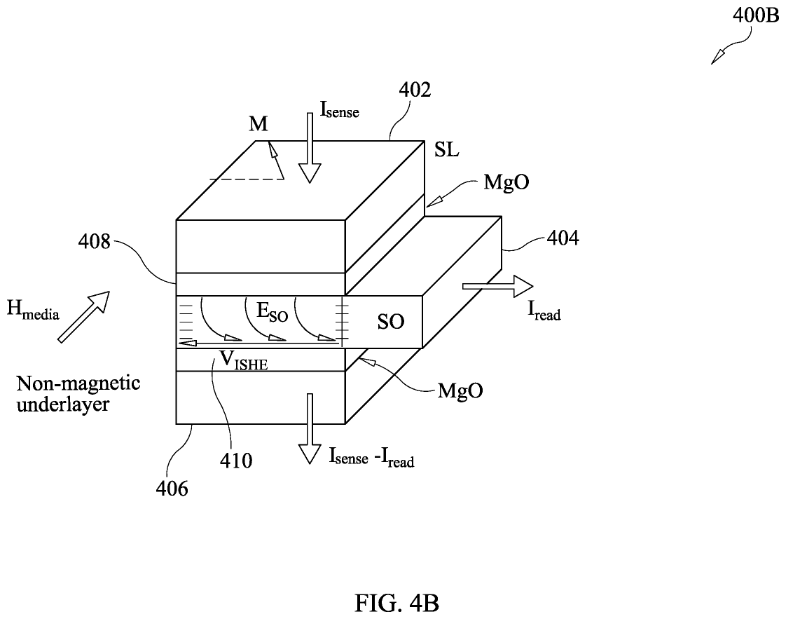

The exponential dependence can originate from the fact that the spin current which penetrates in the SO layer gets gradually depolarized on a length scale given by the spin-diffusion length in this layer noted ss. As represented in FIG. 3, depending on the sign of the field from media (upward or downward), the magnetization of the sense layer can be pulled upward or downward in the plane of the sense layer so that the spin polarized electrons penetrating in the spin-orbit layer will be either deflected toward the right or towards the left. As a result, a transverse electrical field can arise within the SO layer given by E_{SO}=ρ_{SO}l_{c2}^{3D} where ρ_{SO} is the resistivity of the SO material. Due to this electrical field, a voltage difference can appear in the SO layer in the cross-track direction below the right and left edges of the sense layer as indicated in FIGS. 4A-B by the positive and negative charges.

FIG. 4A is an example illustration of the phenomenon of current back-flow appearing in the ISHE structure if no tunnel barrier or layer with current confined path is introduced between the SO layer and the SL as well as between the SO and the nonmagnetic metallic underlayer. As shown in FIG. 4A, the reader 400A can include a SL layer 402, a SO layer 404, and an underlayer 406. The back-flow current has the detrimental impact of reducing the available read current which can be used to readout the field from media.

FIG. 4B illustrates an example reduction of the back-flow currents in the SL and nonmagnetic underlayer by introducing tunnel barriers or layers with current confined paths at the interfaces between the SO layer and SL and non-magnetic underlayer. For example, in FIG. 4B, a first tunnel barrier 408 can be disposed between the SL layer 402 and SO layer 404. Further, a second tunnel barrier 410 can be disposed between the SO layer 404 and the underlayer 406.

As illustrated in FIG. 4A, if the metallic magnetic SL layer is in direct contact with the SO layer, a back flow current may arise in the SL layer from the positive charges to the negative charges. Similarly, in the metallic underlayer, a back flow current may flow. The back flow current can reduce the amount of current which can be taken aside of the ISHE device to readout the magnetic field from media. It is therefore preferable to get rid of these back-flow currents. For that, a high resistance layer can be inserted between the SO and the two adjacent layers. High resistance can indicate a resistance higher than the resistance of the SO layer in the out-of-plane direction. These layers can be tunnel barriers or layers with confined current paths (so-called CCP layers).

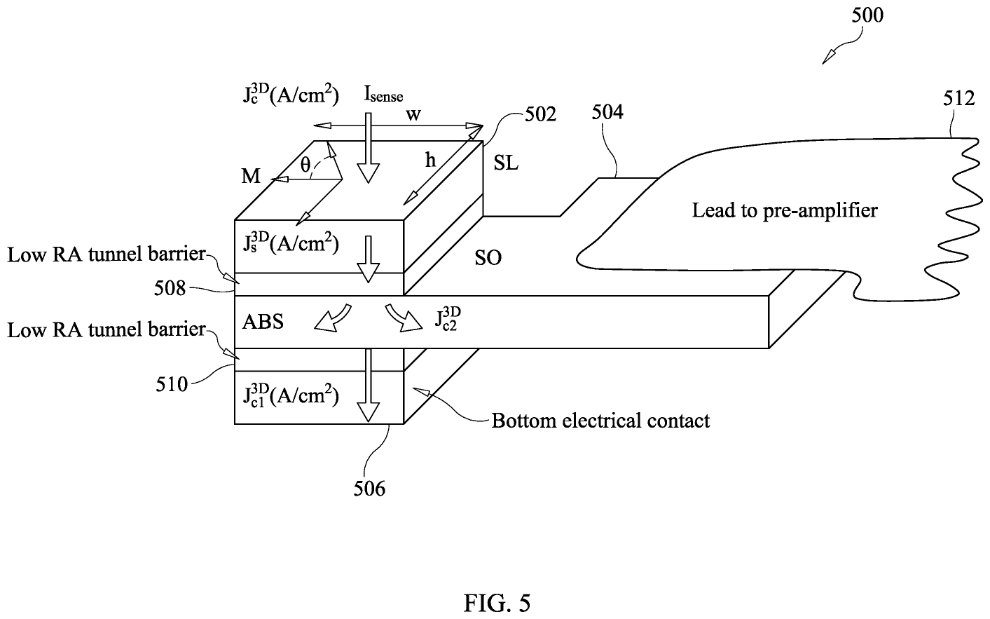

In some instances, these layers are discontinuous tunnel barriers comprising metallic pinholes formed for instance by co-depositing a non-magnetic metallic material such as Cu, Ag or Au with an oxide material such as for instance AlOx, MgO, TaOx or HfOx. The resulting structure is represented in FIG. 5, assuming that the inserted high resistance layers are tunnel barriers. The tunnel barriers can have a low resistance x area (RA) product typically below 10 Ω·μm² and preferably below 0.5 Ω·μm² so that they can withstand a large current density J_{c}^{3D} without dielectric breakdown. For instance, a tunnel barrier with RA=0.5 Ω·μm² traversed by a current of j=4·10⁷ A/cm² can be submitted to a bias voltage of V=jRA=0.2V which is low enough not to induce dielectric breakdown of the tunnel barrier. Besides, the tunnel barrier separating the sense layer from the SO layer can be able to transmit a current of high spin-polarization.

In the presence of a tunnel barrier, the spin polarization may no longer be given by the scattering asymmetry in the sense layer but by the asymmetry in density of states at the interface between the sense layer and the tunnel barrier; and possible additional spin-filtering effect may be occurring during the tunneling process. The tunnel barrier can be made of oxides or nitrides AlOx, TiOx, HfOx, AlN, TiN, and preferably of MgO which is known to provide high spin polarization of tunneling current of the order of 80%. For the second tunnel barrier between the SO layer and the bottom electrical contact, there may not be a need to transmit a highly spin polarized current so that other oxide or nitride tunnel barrier or semiconductor barrier may be used provided they can withstand a relatively high current density of several 10⁷ A/cm² without experiencing dielectric breakdown.

In the configuration described in FIG. 5, the part of the SO layer which is sandwiched between the two tunnel barriers can act like a voltage source having an internal resistance given by the in-plane resistance of this SO part which can be expressed with the notation of FIG. 5 Rᵢₙₜₑᵣₙₐₗ=ρ_{SO}w/(ht_{SO}) where ρ_{SO} is the resistivity of the SO material, w is the width of the sense layer in the crosstrack direction, h is the stripe height in the direction perpendicular to the ABS, t_{SO} is the thickness of the SO layer. Taking as example the case where the SO material would be βW, the resistivity of which is 260 μΩ·cm, assuming w=30 am, h=30 nm, t_{SO}=2 nm, the internal resistance is Rᵢₙₜₑᵣₙₐₗ=1300Ω. In this configuration with a tunnel barrier or a CCP layer introduced between the SO layer and the bottom electrical contact, the width of the bottom electrical contact can be made larger than that of the sense layer.

FIG. 5 illustrates a ISHE head embodiment in which two tunnel barriers have been inserted between the SO layer and the sense layer as well as between the SO layer and the bottom electrical contact to avoid current back flow in these layers. For instance, as shown in FIG. 5, the reader 500 can include a SL layer 502, a SO layer 504, and a bottom layer 506. Further, a first tunnel barrier 508 can be disposed between SL layer 502 and SO layer 504, and a second tunnel barrier 510 can be disposed between SO layer 504 and bottom layer 506. Further, a lead to pre-amplifier 512 can be connected to the SO layer 504.

By integrating the current density J_{c2}^{3D} which is deviated by spin orbit within the SO layer over its thickness t_{SO} and height h, the total deviated current can be written as

$${I}_{ISHE} = {Θ}_{SHE} {l}_{SF}^{SO} h β {j}_{sense} ( 1 - exp ( - \frac{{t}_{SO}}{{l}_{SF}^{SO}} ) ) sin θ where θ$$

is the angle characterizing the rotation of the sense layer magnetization due to the field from media, θ=0 corresponding to the magnetization orientation when the field from media is equal to zero. β represents the spin-polarization of the current entering the SO material. As previously explained, in the case where the sense layer is in direct contact with the SO layer or when a layer with current confined paths (CCP) is introduced at the SL/SO interface, the transport regime can be diffusive and the spin-polarization of the current is then determined by the spin-dependent scattering asymmetry in the magnetic sense layer as explained in Valet and Fert theory. In the case where a tunnel barrier is introduced at the SL/SO interface, the transport regime can be ballistic and the spin-polarization of the tunneling current is then determined by the density of states at the SL/tunnel barrier interface and any other spin-filtering phenomenon which may occur during tunneling as known for instance in the case of MgO tunnel barrier.

Knowing the in-plane internal resistance of the SO layer, Rᵢₙₜₑᵣₙₐₗ=ρ_{SO}w/(ht_{SO}), the ISHE voltage generated across the ISHE device (see FIG. 4b) can be written as

$${V}_{ISHE} = {Θ}_{SHE} {ρ}_{SO} {l}_{SF}^{SO} \frac{w}{{t}_{SO}} β {j}_{sense} ( 1 - exp ( - \frac{{t}_{SO}}{{l}_{SF}^{SO}} ) ) sin θ .$$

To get an order of magnitude of this signal, a case can be considered where the sense layer is based on FeCoB with an MgO layer separating the sense layer from the SO layer assumed to be made of βW. In this case, it can be known from the tunnel magnetoresistance of MgO based magnetic tunnel junction that the spin-current polarization is about 80% so that β=0.8. Using β=0.8. Using Θ_{SHE}=0.33 in βW, ρ_{SO}=260 μΩ·cm, l_{SF}^{SO}=2 nm, w=30 mm, t_{SO}=l_{SF}^{SO}=2 nm, jₛₑₙₛₑ=8·10⁷ A/cm² (corresponding to 0.4V across the tunnel barriers with RA=0.5 Ω·μm²) and assuming that the magnetization rotates in an interval ±θₘₐₓ=±45° due to the varying field from media, this can result in V_{ISHE}=7.4 mV.

The above expression of V_{ISHE} indicates that the dependence of the voltage available for readout varies as a function of the t_{SO} thickness of the SO layer as

$$\frac{1}{{t}_{so}} ( 1 - exp ( - \frac{{t}_{SO}}{{l}_{SF}^{SO}} ) ) ,$$

which is a steadily decreasing function of the SO thickness. This can mean that it is preferable to minimize the SO thickness in terms of signal. This thickness may not be too low nevertheless because the electrical noise increases with the internal resistance of the ISHE device which grows as 1/t_{SO}. In terms of SO material to be used in the device, the above formula can show that the figure of merit of the material is Θ_{SHE}ρ_{SO}l_{SF}^{SO}. Therefore, a material combining large spin Hall angle, high resistivity and long spin-diffusion length can be selected.

Quantitatively, this product can be at least of 50 and preferably at least 150 where Θ_{SHE} is the spin Hall angle of the spin-orbit material (no units), ρ_{SO} is the resistivity of this material expressed in μΩ·cm, and l_{SF}^{SO} is the spin-diffusion length in this material expressed in nm. CuBi alloys and βW both can be materials to achieve this combination since their Θ_{SHE}ρ_{SO}l_{SF}^{SO} product respectively equal 55 and 170.

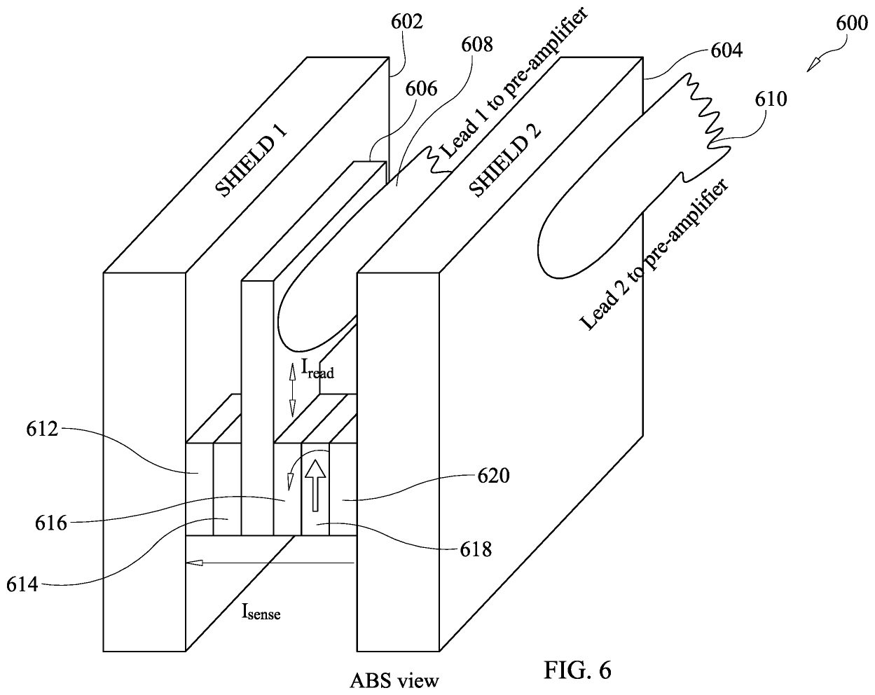

The ISHE device can then be connected to an amplification system which can comprise a pre-amplifier as the first amplification stage. The leads between the ISHE device and this amplification device can have a resistance as low as possible, preferably lower than the internal resistance of the ISHE device. The contact of one of the leads to the amplification device can be taken on the side of the ISHE device, more precisely on the side-part of the SO layer which is not covered by the sense layer as represented in FIG. 6. In order to minimize the overall lead resistance between the ISHE device and the amplification device, it can be preferable to design the shape of the SO layer so that this layer widens as closely as possible from the side-edge of the ISHE device as represented in FIG. 6.

FIG. 6 is an example ABS view of the ISHE reader in which the two connections to the ISHE device are made for the first one on the widen part of the SO layer and for the second one, on one of the two shields. As shown in FIG. 6, the design 600 can include shield layers 602, 604, a SO layer 606, a first lead 608 and a second lead 610. Further, the design 600 can include a magnetic sense layer 618, tunnel barrier layers 614, 616, and conducting layers 612, 620.

The purpose can be to minimize the series resistance of the lead by increasing the width of the SO layer. It can be important to increase the width of the SO layer because this layer is preferably made of a high resistivity material to increase the ISHE voltage. Then on the widened part of the SO layer, a lead of a low resistivity material such as Cu or Al can be connected ensuring a first electrical connection between the ISHE device and the amplifier system.

In a first embodiment, the second electrical contact to the ISHE device can be made via one of the two shields as illustrated in FIG. 6. In this Figure, the device 600 can include a SO layer 606, a magnetization of the magnetic sense layer 618, tunnel barriers or CCP layers 614, 616 separating the SO layer from their adjacent layers. Further, the device 600 can include conducting layers 612, 620 ensuring electrical connections to the shields as well as allowing some magnetic decoupling between the sense layer 606 and the shield 2 604.

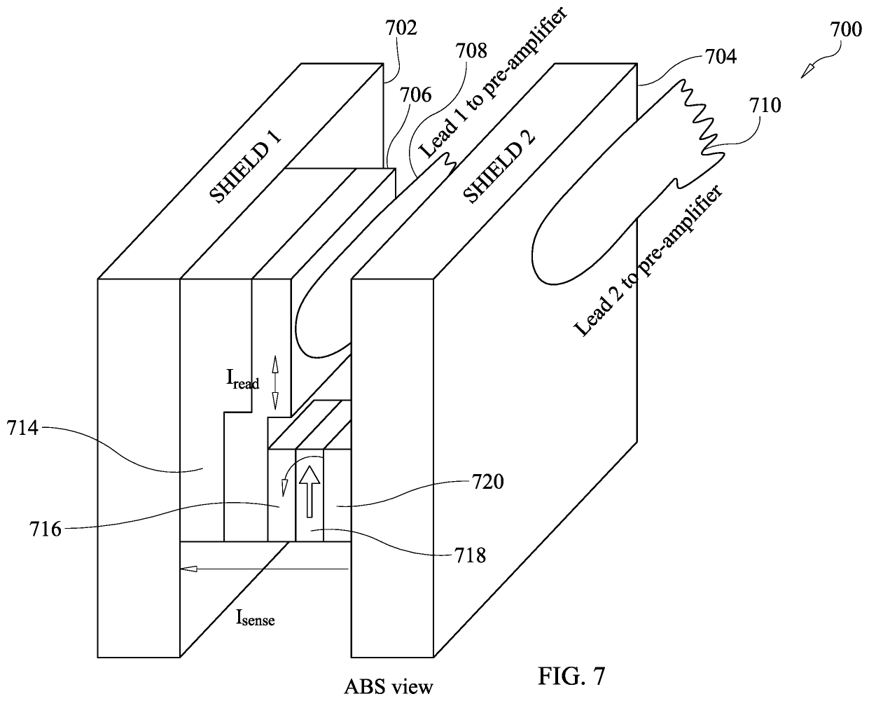

An example composition of the ISHE stack can be from shield 1 to shield 2: Ta2 nm/FeCoB0.4 nm/MgO1 nm/W2 nm/MgO1 nm/FeCoB 5 nm/Ta2 nm representing a total thickness of around 13.4 nm as compared to 25 nm in other readers based on magnetic tunnel junctions. The conducting layer between the second tunnel barrier and shield 1 may not be completely necessary. In some instances, the current can tunnel directly from the SO layer to shield 1. It can be important to maintain a good electrical insulation between shield 1 and the part of the SO layer which extends sideways. This can imply that the oxide layer which is between the part of the SO layer extending aside of the ISHE device and shield 1 can be thicker than the oxide layer used as tunnel barrier within the ISHE device itself as illustrated in FIG. 7, for example.

FIG. 7 is an example ABS view of the ISHE reader in which the bottom conducting layer has been removed so that the sense current tunnel directly from the SO layer to shield 1. The oxide layer separating the SO layer from shield 1 can be thinner at the location of the ISHE device and thicker elsewhere. As shown in FIG. 7, the design 700 can include shields 702, 704, SO layer 706, leads 708, 710, tunnel barriers 714, 716, sense layer 718, and conductive layer 720.

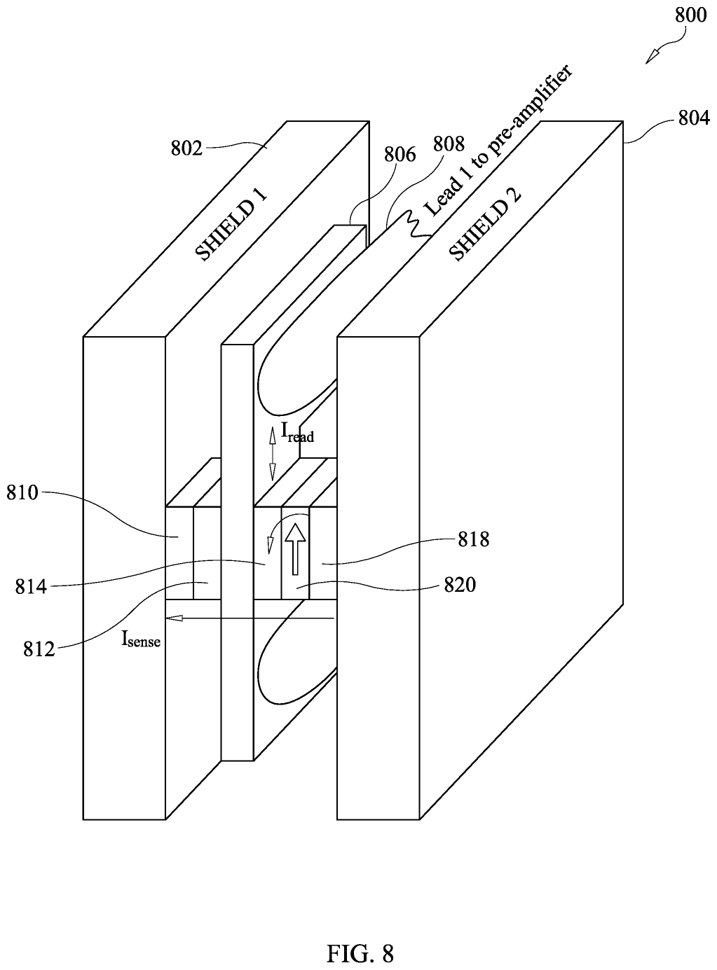

In a second embodiment, the SO layer can extend laterally and symmetrically on both sides of the ISHE device as illustrated in FIG. 8. In this case, similar to the previous embodiment, the SO layer can be patterned with a widened shape on both lateral sides of the ISHE device. In this case, the two electrical connections to the amplification device can be made on the two widened parts of the SO layer on both sides of the ISHE device. This embodiment can mitigate or eliminate magnetic noise originating from the shield. Indeed, the sense current flow in the shield may generate some electrical noise of magnetic origin due to anisotropic magnetoresistance in the shield. Since in the previous embodiment one of the shield can be connected in series with the ISHE device, and can add noise to the ISHE readout signal. In contrast, in this embodiment, the two leads may be connected to the ISHE device. Therefore, the ISHE signal provided to the amplification signal may not be affected here by magnetic fluctuations in the shields. Further, the signal can be increased because it can benefit from the entire drop of potential between the two sides of the ISHE device. This also can provide a true differential sensing scheme further enhancing electrical signal to noise.

In some instances, to save in the shield to shield spacing, the electrons of the sense current can tunnel directly from the SO layer into shield 1 through the thin layer tunnel barrier or CCP layer separating the SO layer from Shield 1. However, as previously mentioned in relation to FIG. 7, a good electrical insulation between the part of the SO layer which extends sideways and shield 1 can be maintained. This can imply that the oxide layer which is used between the part of the SO layer extending to the side of the ISHE device and shield 1 can be thicker than the oxide layer used as tunnel barrier within the ISHE device itself as illustrated in FIG. 7.

FIG. 8 is an example illustration of an ABS view of the ISHE reader in which the two connections to the ISHE device are made on the two widen parts of the SO layer patterned on both sides of the ISHE device. As shown in FIG. 8, the design 800 can include shields 802, 804, SO layer 806, and leads 808, 820, with a second lead 820 being disposed at a second end of the SO layer 806. The design 800 can also include tunnel layers 812, 814, conductive layers 810, 818, and sense layer 816.

The noise of the ISHE device can have two origins: first is electrical (Johnson noise); the other is magnetic due to thermal fluctuations of the sense layer magnetization. The electrical noise can be written as follows: ΔVⱼₒₕₙₛₒₙ=\sqrt{4k_{B}T(Rᵢₙₜₑᵣₙₐₗ+R_{lead})Δf} where k_{B} is the Boltzmann constant, T is the operating temperature of the ISHE device, Rᵢₙₜₑᵣₙₐₗ the previously defined internal resistance of the ISHE device, R_{lead} can include the lead resistance to the amplifier device, M the readout bandwidth. Assuming T=320K, Rᵢₙₜₑᵣₙₐₗ=130052, Read=1000Ω, Δf=2 GHz, then ΔV_{Johnson}=285 μV rms.

The magnetic noise can originate from thermal fluctuations of the magnetization in the sense layer. The sense layer magnetization can fluctuate around its average equilibrium direction by a rms fluctuation amplitude given by

$${θ}_{rms} = \sqrt{\frac{{k}_{B} T}{{μ}_{0} {M}_{S} {H}_{R} V}}$$

where μ₀ is the vacuum permeability, Mₛ the sense layer magnetization, H_{K} the sense layer anisotropy field and V the sense layer volume.

As in all magnetic sensors, the sense layer can be designed so that the thermal angular fluctuations of its magnetization is a small fraction (typically less than a factor ⅕ and preferably less than a factor 1/10) of the angular variation of the sense layer magnetization caused by the variations of magnetic field from media (typically ±45°). To achieve this, the sense layer magnetization can be modified by adjusting its anisotropy field and its volume. Assuming that the sense layer is made of FeCoB alloy with a magnetization of 1.7 10⁶ A/m, H_{K}=60 mT and that it has a width (cross-track) of 30 nm, a stripe height h of 30 nm and a thickness of 6 nm, this can yield θᵣₘₛ=0.11 rad i.e 6°. The corresponding noise on the readout signal ΔV_{mag} is then given by

$$Δ {V}_{mag} = {V}_{ISHE} \frac{sin {θ}_{rms}}{sin {θ}_{max}} .$$

Assuming again θ_{SHE}=0.33 in βW, ρ_{SO}=260μΩ·cm, l_{SF}^{SO}=2 nm, w=30 nm, t_{SO}=l_{SF}^{SO}=2 nm, jₛₑₙₛₑ=8·10⁷ A/cm² (corresponding to 0.4V across the tunnel barriers with RA=0.5·μm²) and that the magnetization rotates in an interval ±θₘₐₓ=±45° due to the varying field from media, V_{ISHE}=7.4 mV and ΔV_{mag}=1.15 mV rms. This can yield a signal to noise ratio

$$SNR = 20 log ( \frac{Δ {V}_{johnson} + Δ {V}_{mag}}{{V}_{ISHE}} ) = 14.2 dB$$

which can be increased by any of: further increasing the thickness of the sense layer taking advantage of the reduced total thickness of the stack compared to TMR reader, or by slightly increasing the stripe height at the expense of a reduced net field from media, or by increasing the anisotropy field in the sense layer at the expense of a weaker rotation of the sense layer magnetization and therefore a reduced readout signal.

In some instances, the sense layer can be above the spin-orbit layer, which can be above the bottom contact layer. The stack can be reversed with the electrical contact layer being at the top and the sense layer at the bottom.

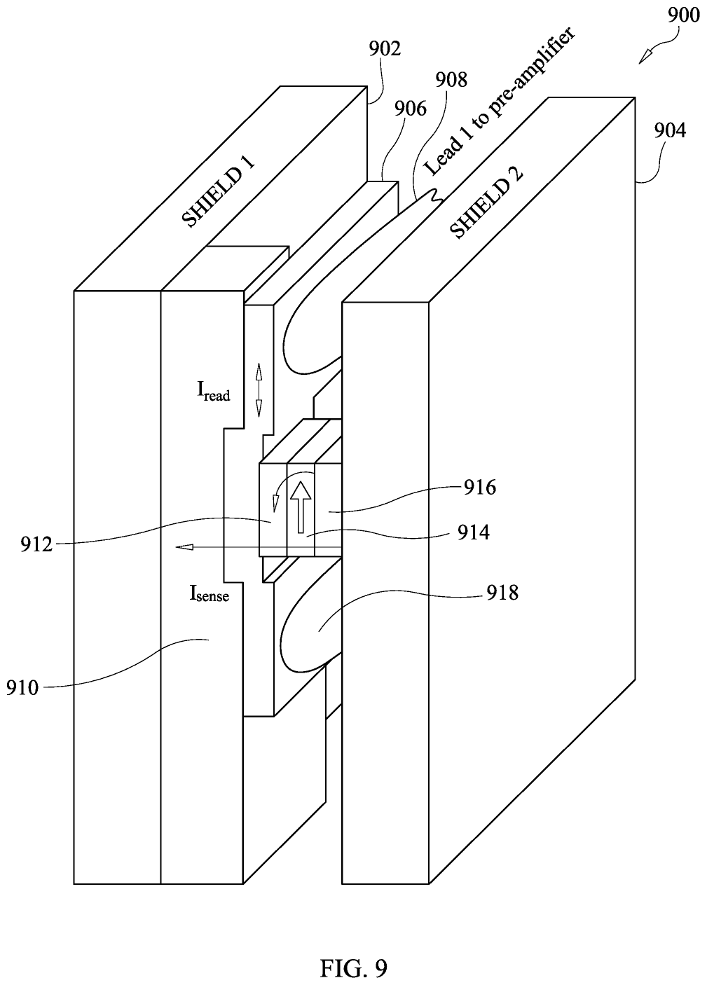

FIG. 9 is an example ABS view of the ISHE reader in which the bottom conducting layer has been removed so that the sense current tunnel directly from the SO layer to shield 1. The oxide layer separating the SO layer from shield 1 can be thinner at the location of the ISHE device and thicker elsewhere. As shown in FIG. 9, the design 900 can include shields 902, 904, SO layer 906, and leads 908, 918, with a second lead 918 being disposed at a second end of the SO layer 906. The design 900 can also include tunnel layers 910, 912, conductive layers 916, and sense layer 914.

It will be understood that terms such as “top,” “bottom,” “above,” “below,” and x-direction, y-direction, and z-direction as used herein as terms of convenience that denote the spatial relationships of parts relative to each other rather than to any specific spatial or gravitational orientation. Thus, the terms are intended to encompass an assembly of component parts regardless of whether the assembly is oriented in the particular orientation shown in the drawings and described in the specification, upside down from that orientation, or any other rotational variation.

It will be appreciated that the term “present invention” as used herein should not be construed to mean that only a single invention having a single essential element or group of elements is presented. Similarly, it will also be appreciated that the term “present invention” encompasses a number of separate innovations, which can each be considered separate inventions. Although the present invention has been described in detail with regards to the preferred embodiments and drawings thereof, it should be apparent to those skilled in the art that various adaptations and modifications of embodiments of the present invention may be accomplished without departing from the spirit and the scope of the invention. Accordingly, it is to be understood that the detailed description and the accompanying drawings as set forth hereinabove are not intended to limit the breadth of the present invention, which should be inferred only from the following claims and their appropriately construed legal equivalents.

What is claimed is:

1. A spintronic reader for a hard disk drive comprising:
a stack of layers providing an inverse spin hall effect (ISHE) including:
a sense layer with a magnetization configured to be biased primarily in a cross-track direction relative to an air-bearing surface (ABS), the sense layer comprising a first length at the ABS in the cross-track direction;
a spin-orbit layer, wherein the spin-orbit layer comprises a second length of a first side that is greater than the first length of the sense layer at the ABS in the cross-track direction, and wherein the spin-orbit layer is characterized by a spin hall angle; and
an electrical contact layer disposed adjacent to the spin-orbit layer to enable an electrical current to flow throughout the sense layer and spin-orbit layer.

2. The spintronic reader of claim 1, wherein the spin-orbit layer is configured to enable electrical contacts to be disposed over a first area of the spin-orbit layer that extends beyond a second area covered by the sense layer.

3. The spintronic reader of claim 1, wherein the spin hall angle is larger than 8% or larger than 30% in absolute values.

4. The spintronic reader of claim 1, further comprising:
an electrical component configured to flow a spin-polarized current in a direction perpendicular to a plane direction throughout the sense layer and the spin-orbit layer.

5. The spintronic reader of claim 1, further comprising:
an output amplifier device comprising a pre-amplifier.

6. The spintronic reader of claim 5, wherein a first conductor is configured to electrically connect an area of the spin-orbit layer not covered by the sense layer to a first input of the output amplifier device, wherein a second input of the output amplifier device is connected to any of bottom or a top layer of the stack.

7. The spintronic reader of claim 1, wherein the sense layer comprises any of a first set of materials comprising Iron (Fe), Cobalt (Co), Nickel (Ni), or any of the first set of materials with an addition of any of Boron (B), Niobium (Nb), Zirconium (Zr), or Hafnium (Hr).

8. The spintronic reader of claim 1, wherein the spin orbit layer is made of a material with a large spin-orbit interaction including any of Tantalum (Ta), Platinum (Pt), Tungsten (W), Bismuth (Bi), Gold (Au), a CuBi alloy, a AuW alloy.

9. The spintronic reader of claim 1, further comprising:
a first tunnel barrier disposed between the sense layer and the spin-orbit layer, wherein the first tunnel has a resistance area product below 5 ohms per squared micrometer (Ω·μm²).

10. The spintronic reader of claim 9, further comprising:
a second tunnel barrier disposed between spin-orbit layer and the electrical contact layer, wherein any of the first tunnel barrier and second tunnel barrier comprise any of Aluminum oxide (AlOx), Titanium Oxide (TiOx), Hafnium Oxide (HfOx), Tantalum Oxide (TaOx), Aluminum nitride (AlNx), Titanium nitride (TiNx), Magnesium Oxide (MgO).

11. The spintronic reader of claim 10, wherein each of the first tunnel barrier and the second tunnel barrier comprise layers each with current confined paths, wherein the current confined paths are formed by mixing a metallic non-magnetic material with an oxide material.

12. The spintronic reader of claim 1, wherein the spin-orbit layer comprises a length of a second side of the spin-orbit layer that is greater than the first length of the sense layer such that the spin-orbit layer extends past each opposing side of the sense layer at the ABS surface in the cross-track direction.

13. A reader stack comprising:
a sense layer with a magnetization configured to be biased primarily in a cross-track direction relative to an air-bearing surface (ABS);
a spin-orbit layer providing a first spin-orbit magnetization, and wherein the spin-orbit layer configured to provide a spin hall angle; and
an electrical contact layer disposed adjacent to the spin-orbit layer to provide a second spin-orbit magnetization opposite to the first spin-orbit magnetization directed at the sense layer.

14. The reader stack of claim 13, wherein the sense layer comprises a first length at the ABS in the cross-track direction, and wherein the spin-orbit layer comprises a second length of a first side that is greater than the first length of the sense layer at the ABS in the cross-track direction.

15. The reader stack of claim 13, further comprising:
a first magnetic shield disposed at a first end of the reader stack and a second magnetic shield disposed at a second end of the reader stack.

16. The reader stack of claim 13, further comprising:
a first tunnel barrier disposed between the sense layer and the spin-orbit layer, wherein the first tunnel has a resistance area product below 5 ohms per squared micrometer (Ω·μm²); and
a second tunnel barrier disposed between spin-orbit layer and the electrical contact layer, wherein any of the first tunnel barrier and second tunnel barrier comprise any of Aluminum oxide (AlOx), Titanium Oxide (TiOx), Hafnium Oxide (HfOx), Tantalum Oxide (TaOx), Aluminum nitride (AlNx), Titanium nitride (TiNx), Magnesium Oxide (MgO).

17. The spintronic reader of claim 16, wherein each of the first tunnel barrier and the second tunnel barrier comprise layers each with current confined paths, wherein the current confined paths are formed by mixing a metallic non-magnetic material with an oxide material.

18. A method comprising:
forming a stack of layers providing an inverse spin hall effect (ISHE) for a spintronic reader of a hard disk drive by:
providing a sense layer with a magnetization configured to be biased primarily in a cross-track direction relative to an air-bearing surface (ABS), the sense layer comprising a first length at the ABS in the cross-track direction;
disposing a spin-orbit layer, wherein the spin-orbit layer comprises a second length of a first side that is greater than the first length of the sense layer at the ABS in the cross-track direction, and wherein the spin-orbit layer is characterized by a spin hall angle; and
disposing an electrical contact layer adjacent to the spin-orbit layer to enable a current to flow throughout the sense layer and spin orbit layer; and
disposing a first magnetic shield at a first end of the stack and a second magnetic shield disposed at a second end of the stack.

19. The method of claim 18, further comprising:
providing a current by an electrical component to flow a spin-polarized current in a direction perpendicular to a plane direction throughout the sense layer and the spin-orbit layer.

20. The method of claim 18, further comprising:
forming a first tunnel barrier disposed between the sense layer and the spin-orbit layer, wherein the first tunnel has a resistance area product below 5 ohms per squared micrometer (Ω·μm²); and
forming a second tunnel barrier disposed between spin-orbit layer and the electrical contact layer, wherein any of the first tunnel barrier and second tunnel barrier comprise any of Aluminum oxide (AlOx), Titanium Oxide (TiOx), Hafnium Oxide (HfOx), Tantalum Oxide (TaOx), Aluminum nitride (AlNx), Titanium nitride (TiNx), Magnesium Oxide (MgO).
